(19) United States
(12) Patent Application Publication
(10) Pub. No.: US 2026/0017429 A1
(43) Pub. Date: Jan. 15, 2026

(54) COMPUTER-IMPLEMENTED METHOD FOR ASSIGNING A PLURALITY OF SIMULATION TASKS TO A PLURALITY OF SIMULATION AGENTS AND CORRESPONDING DEVICE FOR DATA PROCESSING

(71) Applicant: dSPACE GmbH, Paderborn (DE)

(72) Inventors: Thomas JAEGER, Paderborn (DE); Markus KOCH, Paderborn (DE); Eugen SELBSTREICH, Paderborn (DE); Thomas MISCH, Paderborn (DE)

(73) Assignee: dSPACE GmbH, Paderborn (DE)

(21) Appl. No.: 19/258,986

(22) Filed: Jul. 3, 2025

(30) Foreign Application Priority Data
Jul. 12, 2024 (DE) 10 2024 119 874.5

(51) Int. Cl. G06F 30/20

(52) U.S. Cl. CPC G06F 30/20

(57) ABSTRACT

A computer-implemented method for assigning a plurality of simulation tasks to a plurality of simulation agents. A simulation task processing list is received, which comprises several simulation tasks to be completed. The simulation tasks to be completed are assigned to the simulation agents such that not all simulation tasks present in the simulation task processing list are assigned to the simulation agents. For the unassigned simulation tasks, it is checked whether simulation task-dependent data of the simulation task are at least partially identical to the simulation task-dependent data of the assigned simulation tasks. At least one unassigned simulation task is assigned to a simulation agent such that after the previously assigned simulation task has been completed, the simulation agent is assigned another simulation task, the simulation task-dependent data of which are at least partially identical to the simulation task-dependent data of the simulation task assigned immediately before it.

This nonprovisional application claims priority under 35 U.S.C. § 119(a) to German Patent Application No. 10 2024 119 874.5 which was filed in Germany on Jul. 12, 2024, and which is herein incorporated by reference.

### BACKGROUND OF THE INVENTION

### Field of the Invention

The invention relates to a computer-implemented method for assigning a plurality of simulation tasks to a plurality of simulation agents. The invention also relates to a data processing device, comprising means for carrying out the above method. Furthermore, the invention relates to a computer program product, comprising commands which, when executed by a computer, cause it to perform the above method. Moreover, the invention also relates to a computer-readable data carrier on which the above computer program product is stored.

### Description of the Background Art

Driver assistance systems such as adaptive cruise control and/or functions for highly automated or autonomous driving can be verified or validated using various verification methods. For example, for functional tests of software of electronic control units (ECUs), hardware in the form of the control unit or in the form of an ECU prototype can be used and the control software can be tested in real road tests. However, in addition to the high costs and the very high time expenditure, the lack of reproducibility due to the complex environmental conditions is problematic for such tests.

Furthermore, so-called Hardware in the Loop (HiL) tests are available, in which the ECU is connected to a HiL simulator via inputs and outputs, wherein the HiL simulator replicates the real environment. The HiL simulator emulates the electrical signals from sensors and actuators that are read by the ECU. For example, in a HiL test of an internal combustion engine, the signals from crankshaft and camshaft sensors are generated by an Angular Processing Unit (APU), which is part of the HiL simulator's hardware. The ECU, in turn, generates sensor and/or actuator control signals based on these signals by means of the control software, which in turn lead to a change in the electrical signals in the HiL simulator. The route, which would be driven as a test track in the real road test and thus generate different electrical signals for the control unit, is mapped as a route model within the HiL simulation. In order to carry out a HiL test, however, the development of an ECU must already be relatively advanced, as the ECU is connected to the HiL simulator as hardware.

Hardware-independent software testing is required to enable earlier testing of the control software, for example at a development point when no hardware is yet available. Virtual ECUs, also known as V-ECUs, can be used for this purpose. A virtual ECU is used to emulate a real ECU in a simulation scenario. In order to create virtual ECUs that are as realistic as possible, a virtual ECU can be created on the basis of the control software of the real ECU. Of course, some components of the control software of the real ECU must be adapted to the virtual environment of the simulation platform. This procedure usually has the goal of simulating a real control unit as much as possible.

However, the relocation of virtual tests to ever earlier development phases leads to changed requirements, in which the focus is no longer on imitating the behavior of a specific ECU as much as possible, but in which a wide variety of applications are to be tested in a flexible and highly modular environment. This is usually done through reproducible, deterministic test drives with a virtual vehicle in a virtual environment. The vehicle, the environment, and the test cases—i.e., the traffic scenarios—can all be freely defined by the user. In this way, new algorithms for vehicle control in virtualized, autonomous vehicles can be tested, among other things.

A possible traffic scenario to consider is, for example, a so-called cut-in scenario. The cut-in scenario refers to a traffic situation in which a highly automated or autonomous vehicle—hereinafter referred to as an ego vehicle—drives in a given lane. Another vehicle cuts from another lane into the lane of the ego vehicle at a certain distance from the ego vehicle and at a reduced speed as compared to the ego vehicle.

In the traffic scenario, it is usually provided that the speed of the ego vehicle and the other vehicle is initially constant. However, since the speed of the ego vehicle is higher than that of the other vehicle, the ego vehicle must be braked to avoid a collision with the other vehicle.

The traffic scenario can be simulated with different parameter values, for example different distances between the ego vehicle and the other vehicle when cutting in, or different speed differences between the ego vehicle and the other vehicle. In order to gain as much knowledge as possible from the simulation, many different simulation runs are carried out in the possible parameter space. Complex traffic scenarios have many parameters and thus a very large parameter space to be covered, so that typically more than one hundred thousand simulation runs have to be carried out to cover the test space. Accordingly, such simulations are resource- and/or time-intensive.

### SUMMARY OF THE INVENTION

It is therefore an object of the invention to provide a method and device to simulate in a more resource-saving and/or cost-saving manner.

According to an example of the invention, a computer-implemented method for assigning a plurality of simulation tasks to a plurality of simulation agents is provided, comprising the steps of: receiving a simulation task processing list comprising several simulation tasks to be completed; assigning the simulation tasks to be completed to the simulation agents in such a way that not all simulation tasks present in the simulation task processing list are assigned to the simulation agents; for the unassigned simulation tasks, checking whether simulation task-dependent data of the simulation task is at least partially identical to the simulation task-dependent data of the assigned simulation tasks; and assigning at least one unassigned simulation task to a simulation agent, taking into account the check performed, in such a way that after the previously assigned simulation task has been completed, the simulation agent is assigned another simulation task, the simulation task-dependent data of which are at least partially identical to the simulation task-dependent data of the simulation task assigned immediately before it.

An aspect of the invention is that not all simulation tasks to be completed—hereinafter also referred to as jobs—are directly distributed to the available simulation agents. Another aspect of the invention is that a check takes place as to what extent the simulation task-dependent data of the unassigned jobs are identical to the simulation task-dependent data of the assigned jobs. Since not all jobs are assigned directly and this check is carried out, the further assignment of the jobs, taking into account the check, can be carried out in such a way that at least one simulation agent is assigned another job after the end of its job, which has at least partially identical simulation task-dependent data. Thus, the method for assigning the plurality of simulation tasks to the plurality of simulation agents enables that the simulation on the simulation agent handles the simulation task-dependent data of the simulation in a resource-saving way, and that this data on the simulation agent does not have to be deleted and reinitiated unnecessarily. In other words, the method according to the invention is a scheduling method. In contrast to scheduling methods, in which the orders are simply completed in the order of the queue, the present method does not necessarily assign the simulation tasks to the simulation agents in the order in which they appear in the simulation task processing list. Instead, the assignment is preferably based on the simulation task-dependent data of the simulation task assigned directly previously to the simulation agent. In other words, in the last step, the unassigned simulation tasks are assigned to the simulation agents, taking into account the check performed, wherein at least one simulation task is assigned in such a way that, after the previously assigned simulation task has been completed, the simulation agent is assigned another simulation task, the simulation task-dependent data of which is at least partially identical to the simulation task-dependent data of the directly preceding simulation task.

It is preferable that all unassigned simulation tasks are assigned to the simulation agents, taking into account the check performed, in such a way that the probability of the occurrence of the simulation agent being assigned another simulation task after the end of the assigned simulation task, the simulation task-dependent data of which is at least partially identical to the immediately preceding assigned simulation task, is maximized as much as possible for the received simulation task processing list.

It is further preferable that the step of checking for the unassigned simulation tasks to see whether or not the simulation task-dependent data of the simulation task are at least partially identical to the simulation task-dependent data of the assigned simulation tasks includes checking whether the simulation task-dependent data of the unassigned simulation tasks are completely identical to the simulation task-dependent data of the assigned simulation tasks. In other words, it is particularly preferable to determine during the check to see whether the simulation task-dependent data of an assigned simulation task are completely identical or partially identical to the simulation task-dependent data of a simulation task that has not yet been assigned. It is also preferably determined how high the proportion of identical simulation task-dependent data is. In this context, it is also preferable that the assignment of at least one unassigned simulation task to a simulation agent, taking into account the check performed, is carried out in such a way that the simulation agent is assigned at least one more simulation task after the previously assigned simulation task has been completed, the simulation task-dependent data of which are completely identical to the simulation task-dependent data of the immediately preceding assigned simulation task. This leads to a particularly large saving of resources. It is also preferable that the assignment of the unassigned simulation tasks to the simulation agents, taking into account the proportion of identical simulation task-dependent data, is carried out in such a way that the simulation agent with the largest share is assigned the simulation task.

In the present case, a simulation task—also referred to as a job—can be understood to be an instruction to the simulation agent to perform a specific simulation. The received simulation task processing list preferably includes at least one unique identifier that the simulation agent can use to identify the simulation to be performed in order to implement the instruction to run the simulation. In the present case, the statement that the simulation agent is assigned another simulation task after the previously assigned simulation task has been completed means that the simulation agent has implemented the first instruction and has performed the specific simulation before the next simulation task is assigned.

The simulation agent can be the instance of a computing environment that performs the simulation. Preferably, several simulation agents are operated in parallel on the computing environment.

In this case, simulation can be understood to mean the implementation of a simulation model. The simulation model represents an abstraction of the system to be simulated, for example in its structure, function, and/or behavior. A simulation is specified by concrete parameter values for a parameter set with which the simulation is performed. In the context of simulations, the parameter set refers to those aspects of the simulation model that have been deliberately designed to be flexible. By feeding the simulation model with concrete values for the parameters of the parameter set, the simulation model is placed in a certain state, the behavior of which is then simulated. In other words, performing the simulation requires the definition of concrete values for the parameters of the parameter set. The simulation is carried out using the simulation agent. After the simulation has been carried out, its results can be interpreted and transferred to the system to be simulated.

Performing the simulation therefore can mean setting a functional simulation model in motion and observing its behavior in certain situations. Depending on the complexity of the model, this process can be lengthy and computationally intensive. In particular, the execution of a specific simulation is usually not sufficient to gain knowledge about the system to be tested. Instead, a large number of simulations are regularly carried out, typically in the order of 100,000. Accordingly, the value for exactly one of the parameters of the parameter set can then be specifically varied, for example, over several simulations, so that the possibly different results of the simulations carried out can be traced back to the influence of exactly this parameter. If several parameters are to be varied systematically and purposefully and/or interactions between the parameters are to be understood, it is necessary, as already mentioned, to perform a large number of simulations.

In the context of control software for control units in the automotive sector, the parameter sets can typically be used to define the traffic scenarios and/or test cases with which a software to be tested, such as control software, is to be tested. In addition, the parameter sets define the simulation environment of the software to be tested. The software to be tested is also known as software under test (SUT).

While the simulation is being performed on the simulation agent, the simulation model interacts with the SUT by outputting input values to the SUT and by recording output values from the SUT. The simulation model calculates the simulation environment of the SUT. For example, in the case of a motor control system as SUT, the physical processes in an (electric) motor and the resulting sensor data represent the simulation environment of the motor control system. In an autonomous driving function as SUT, on the other hand, the vehicle's environment and the resulting data streams from the simulated environment sensors represent the simulation environment of the driving function. Furthermore, the simulation model also calculates the output values for the traffic scenarios or test cases. A test case can be, for example, a failure of the cooling system in the case of a motor control system and the cutting in of another vehicle in the case of a driving function. Test cases each include a pair of input values and the expected output values. The calculation of the output values is taken over by the simulation model.

In the present case, simulation task-dependent data may refer to all data that depend on a specific simulation and can therefore potentially be different for each simulation specified by the simulation task. For example, the parameter sets described above for the traffic scenarios and/or test cases and the simulation environment of the SUT are simulation task-dependent data. In addition, the SUT is also simulation-task-dependent data. Due to the way in which knowledge is gained, many of the simulations carried out (in the order of 100,000) have partially identical simulation task-dependent data. For example, if multiple simulations are run with the same simulation environment, the simulation task-dependent data of the multiple simulations will also be partially identical, because the simulation task-dependent data related to the simulation environment will not differ from each other.

Correspondingly, the present method, in which the assignment of at least one unassigned simulation task to a simulation agent is carried out in such a way that the simulation agent can be assigned another simulation task after the previously assigned simulation task has been completed, the simulation task-dependent data of which is at least partially identical to the simulation task-dependent data of the simulation task assigned directly before it, allows for immense saving of resources. In particular, time savings in the range of 10 to 60 seconds per simulation can be saved if the simulation task-dependent data on the simulation agent does not have to be reinitiated for each simulation. This can lead to time savings of up to 69 days for 100,000 simulations.

The step of assigning simulation tasks to be completed to the simulation agents can be done in such a way that not all simulation tasks present in the simulation task processing list are assigned to the simulation agents, involves assigning the simulation tasks to be completed to the simulation agents in such a way that no more than one simulation task is assigned to each simulation agent. Preferably, therefore, exactly the number of jobs that corresponds to the number of available simulation agents is assigned to the simulation agents. For example, if there are 10 simulation agents, 10 simulation tasks in the simulation task processing list will be distributed.

The simulation agent can be instructed not to remove the simulation task-dependent data after the simulation task has been completed. This allows for the simulation agent to reuse some or all of the simulation task-dependent data at the next assignment. Especially in multi-client systems, cleanup is performed by default after a task is completed, and client-dependent data are deleted. In the present case, it is preferred that this is not carried out in order to enable the reuse of the simulation task-dependent data. In the present case, a multi-client system is understood to be a system with which several clients, i.e., clients or customers, can be served from the same server or by means of the same software, without the clients mutually seeing their data, user administration and the like.

The simulation agent can be instructed to adopt the simulation task-dependent data of the previously completed simulation task identified as identical for the assigned simulation task before the simulation task begins. This eliminates the need to reinitiate the simulation task-dependent data identified as identical on the simulation agent, saving resources.

The simulation agent can be instructed to remove the simulation task-dependent data of the previously completed simulation task that have been identified as non-identical before the simulation task begins. In other words, the deletion of simulation task-dependent data is not carried out after a simulation has been completed, but is carried out before the simulation begins, if necessary. Accordingly, only the simulation task-dependent data identified as non-identical must be deleted and reinitiated.

The step of assigning the unassigned simulation tasks to the simulation agents can be carried out taking into account the check in such a way that a simulation task in the simulation task processing list is not assigned until a simulation agent has completed a previously assigned simulation task. Running a simulation from the simulation agent usually takes different amounts of time, for example, because the simulations are of varying complexity. In addition, it is also possible that a simulation is terminated prematurely because an error condition is met. Due to the different runtimes, it is advantageous to assign only individual simulation tasks to the simulation agents at a time in order to prevent certain simulation agents from completing the assigned simulation task prematurely without there being any more unassigned simulation tasks on the simulation task processing list.

The step of receiving a simulation task processing list comprising several simulation tasks to be completed can include receiving an updated simulation task processing list. In other words, the simulation task processing list is preferably populated with new simulation tasks, which were initiated by a user during the runtime of the simulations, for example. The simulation tasks that have been added to the updated simulation task processing list are preferably not yet assigned to a simulation agent and are also preferably checked to see whether the simulation task-dependent data of the simulation task is at least partially identical to the simulation task-dependent data of the assigned simulation tasks. This also makes it possible to assign the newly added simulation tasks, preferably by taking into account the check carried out on a simulation agent, in such a way that the simulation agent is assigned another simulation task after the previously assigned simulation task has been completed, the simulation task-dependent data of which is at least partially identical to the simulation task-dependent data of the simulation task assigned directly before.

The step of assigning the unassigned simulation tasks to the simulation agents can be carried out taking into account the check in such a way that a simulation agent is only assigned an unassigned simulation task with non-identical simulation task-dependent data when there are no more simulation tasks in the simulation task processing list, the simulation task-dependent data of which is completely identical to the simulation task-dependent data of the simulation tasks previously assigned to that simulation agent. In other words, a specific simulation agent is assigned the appropriate simulation tasks in relation to the simulation task-dependent data until there are none left in the simulation task processing list. This ensures that as many resources as possible are saved.

The assignment of the unassigned simulation tasks to the simulation agents, taking into account the check, can be carried out in such a way that a period of time for how long an unassigned simulation task is in the simulation task processing list is also taken into account. This ensures that no simulation task is stuck in the simulation task completion list for a very long period of time, even if receiving an updated simulation task processing list adds new unassigned simulation tasks that have a higher proportion of identical simulation task-dependent data with previously assigned simulation tasks.

The step of checking for the unassigned simulation tasks to see whether simulation task-dependent data of the simulation task can be at least partially identical to the simulation task-dependent data of the assigned simulation tasks includes checking whether the unassigned simulation task is attributable to the same client as the assigned simulation task.

The probability that the simulation task-dependent data of the simulation task are at least partially identical is many times higher for simulation tasks that are attributable to the same client than for simulation tasks that are not attributable to the same client. Thus, by checking whether the unassigned simulation task is attributable to the same client as the assigned simulation task, it is possible to quickly estimate whether further identification of partially identical simulation task-dependent data should be carried out. It is also preferable that if the check shows that the unassigned simulation task is not attributable to the same client as the assigned simulation task, the simulation agent is instructed to remove all simulation task-dependent data from the previously completed simulation task before the simulation task begins. This is particularly advantageous in order to be able to provide a multi-client system.

It is also provided that the step of checking for the unassigned simulation tasks to see whether simulation task-dependent data of the simulation task are at least partially identical to the simulation task-dependent data of the assigned simulation tasks can include checking whether the simulation task-dependent data are cross-client data or client-specific data. It is particularly preferable that in the case of cross-client data, the simulation agent is instructed to adopt the cross-client simulation task-dependent data of the previously completed simulation task for the assigned simulation task that has been identified as identical before the simulation task begins. On the other hand, in the case of client-specific data, it is preferably provided that the simulation agent is only instructed to accept the client-specific simulation task-dependent data of the previously completed simulation task that has been identified as identical for the assigned simulation task before the simulation task begins, if the unassigned simulation task is attributable to the same client as the assigned simulation task.

The simulation task-dependent data can include parameter sets for traffic scenarios and/or test cases of a simulation specified by the simulation task, a software to be tested (SUT) and/or a simulation environment of the simulation specified by the simulation task.

Further technical features and advantages will be apparent to the person skilled in the art from the following description of a data processing device, a computer program product, and/or a computer-readable data carrier, as well as from the exemplary embodiment.

The object is also achieved by a device, such as a computer having a processor, memory, and/or display, for data processing for carrying out the method described above. Preferably, the data processing device can be a server-based device. This allows the user to avoid having hardware resources for performing the method of assigning a plurality of simulation tasks to a plurality of simulation agents, as the method is performed on a server.

Furthermore, the invention relates to a computer program product, comprising commands which, when executed by a computer, cause it to execute the above method.

In addition, the invention relates to a computer-readable data carrier on which the above computer program product is stored. Preferably, the commands are embedded on the computer-readable disk, and the commands, when executed by a computer processor, cause the processor to perform the method for generating the modification proposal for at least one simulation run that executes a large number of simulation runs.

The technical advantages and effects of the data processing device, the computer program product and the computer-readable data carrier are apparent to the skilled person from the description of the method for assigning a plurality of simulation tasks to a plurality of simulation agents, as well as from the example described below.

The invention is explained in more detail below with reference to the drawing. The example shown is strongly schematized, i.e., distances, dimensions and measurements are not to scale and, unless otherwise stated, do not have any derivable geometric relations to each other.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically, a representation of assigning simulation tasks to simulation agents performed in a method for assigning a plurality of simulation tasks to a plurality of simulation agents according to an example of the invention; and

FIG. 2 schematically, representation of assigning simulation tasks to simulation agents performed in a method for assigning a plurality of simulation tasks to a plurality of simulation agents, according to an example of the invention.

### DETAILED DESCRIPTION

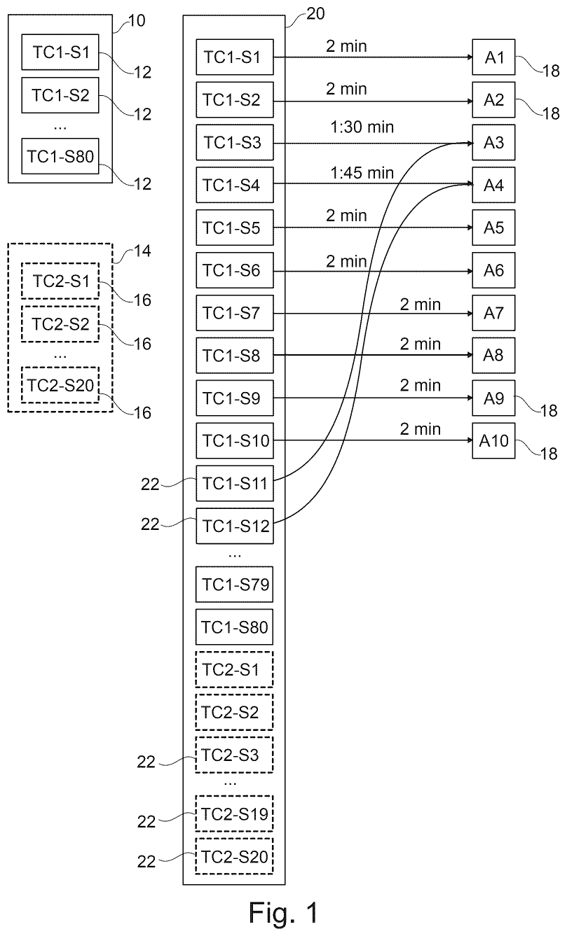

In the following, an example of a computer-implemented method for assigning a plurality of simulation tasks 22 to a plurality of simulation agents 18 is explained with reference to FIG. 1.

A scenario-based testing of a driving function is to be carried out, in which two scenarios 10, 14 are to be run through. In the first scenario 10 (also called test case), 80 parameter variations are to be simulated, which thus leads to 80 concrete simulations 12 to be performed. In the second scenario 14, 20 parameter variations are to be simulated, resulting in 20 concrete simulations 16 to be performed. Ten simulation agents 18 are available for simulation.

In the first step of the method, a simulation task processing list 20 is received. This includes the present simulation tasks to be completed 22. Since the user created the simulations 12 with the first scenario 10 first, they also appear first in the simulation task processing list 20. The simulation task processing list 20, as shown in FIG. 1, is as follows in the following example:
TC1_S1, TC1_S2, TC1_S3, . . . TC1_S79, TC1_S80, TC2_S1, TC2_S2, TC2_S3, . . . TC2_S19, TC2_S20,

where TC1 stands for the first scenario 10, TC2 for the second scenario 14 and S for the concrete simulation 12, 16 to be carried out.

The simulation tasks 22 to be completed are then assigned to the simulation agents 18 in such a way that not all simulation tasks 22 present in the simulation task processing list 20 are assigned to the simulation agents 18. Specifically, this is implemented in the present example by assigning no more than one simulation task 22 to each simulation agent 18. In the present case, this assignment is made in the order in which they are entered in the simulation task processing list 20. This results in the following assignment to the ten simulation agents 18, A1 to A10:

$$\begin{matrix}TC1\_S1 \text{=>} A 1 \\ TC1\_S2 \text{=>} A 2 \\ TC1\_S3 \text{=>} A 3 \\ … \\ TC1\_S9 \text{=>} A 9 \\ TC1\_S10 \text{=>} A 10\end{matrix}$$

Simulation agents 18 are each instructed not to remove the simulation task-dependent data after the simulation task 22 has been completed. When simulation agent 18 has completed an assigned simulation task 22, it is assigned another simulation task 22 from the simulation task processing list 20. In the present example, simulation agent A3 first completes its assigned simulation 12 of the first scenario 10 TC1_S3, so that it is then assigned simulation 12 TC1_S11.

After simulation 12 TC1_S80 has been assigned, simulation 16 of the second scenario 14 TC2_S1 is then assigned. In the present example, this simulation task is assigned to simulation agent 18 A5:

$$TC2\_S1 \text{=>} A 5$$

Since simulation agent 18 A5 has previously performed a simulation 12 with a different scenario—namely with the first scenario 10—simulation agent 18 is instructed to adopt the simulation task-dependent data of the previously completed simulation task 22, which was identified as identical, for the assigned simulation task 22, and to remove the simulation task-dependent data of the previously completed simulation task 22, which was identified as non-identical, before the start of simulation task 22.

At the beginning of the execution of simulation 16 TC2_S1, simulation agent 18 A5 now deletes and reinitiates simulation task-dependent data for the first time.

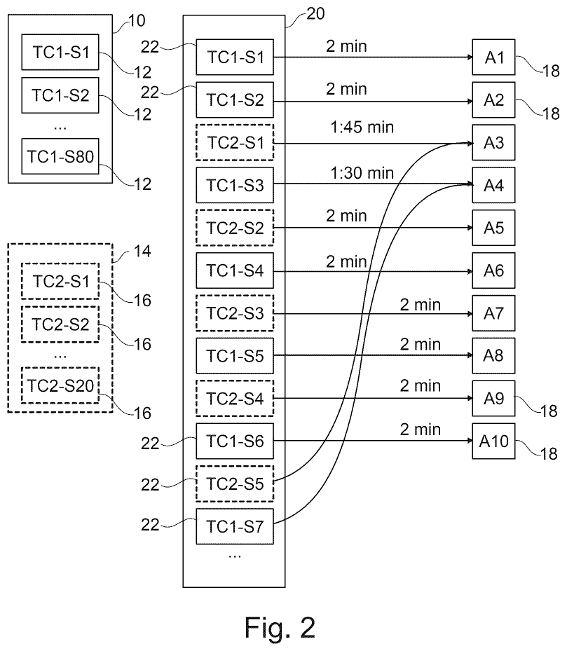

In the following, an example is described with reference to FIG. 2:

In this example, scenario-based testing of a driving function is also to be carried out, in which two scenarios 10, 14 are to be run through. In the first scenario 10, 80 parameter variations are to be simulated, resulting in 80 concrete simulations 12 to be performed. In the second scenario 14, 20 parameter variations are to be simulated, resulting in 20 concrete simulations 16 to be performed. Ten simulation agents 18 are available for simulation.

In the first step of the method, the simulation task processing list 20 is received. This includes the simulation tasks 22 to be completed. Since simulations 12, 16 were created in parallel with the first scenario 10 and the second scenario 14, the simulation task processing list 20 in this example is as follows (with simulation tasks 22 of the second scenario 14 shown in italics for easier representation):
TC1_S1, TC1_S2, TC2_S1, TC1_S3, TC2_S2, TC1_S4, TC2_S3, TC1_S5, TC2_S4,
TC1_S6, TC2_S5, TC1_S7, TC2_S6, . . . TC1_S21, TC2_S20, TC1_S22, TC1_S23,
. . . TC1_S80

where TC1 stands for the first scenario 10, TC2 for the second scenario 14 and S for the concrete simulation 12, 16 to be carried out.

Then, no more than one simulation task 22 is assigned to each simulation agent 18 in the order in which they are entered in the simulation task completion list 20. This results in the following assignment to the 10 simulation agents 18 A1 to A10:

$$\begin{matrix}TC1\_S1 \text{=>} A 1 \\ TC1\_S2 \text{=>} A 2 \\ TC2\_S1 \text{=>} A 3 \\ \begin{matrix}TC1\_S3 \text{=>} A 4 \\ TC2\_S2 \text{=>} A 5 \\ TC1\_S4 \text{=>} A 6 \\ TC2\_S3 \text{=>} A 7 \\ TC1\_S5 \text{=>} A 8\end{matrix} \\ TC2\_S4 \text{=>} A 9 \\ TC1\_S6 \text{=>} A 10\end{matrix}$$

Furthermore, for the unassigned simulation tasks 22 on the simulation task processing list 20, a check takes place to see whether simulation task-dependent data of simulation task 22 are at least partially identical to the simulation task-dependent data of assigned simulation tasks 22. The further assignment of the unassigned simulation tasks 22 to the simulation agents 18 is then carried out taking into account the check in such a way that the simulation agent 18 is assigned another simulation task 22 after the previously assigned simulation task 22 has been completed, the simulation task-dependent data of which is at least partially identical to the simulation task-dependent data of the simulation task 22 assigned directly before.

When a simulation agent 18 has completed an assigned simulation task 22, it is assigned another simulation task 22 from the simulation task processing list 20. In the present example, simulation agent 18 A4 first completes its assigned simulation 12 TC1_S3, so that it is then assigned another simulation task 22.

Although the next simulation task 22 in the simulation task processing list 20 is simulation 14 TC2_S5, simulation agent 18 A4 is not assigned this simulation task 14. Instead, simulation 12 TC1_S7 is assigned to simulation agent 18 A4 as simulation task 22 since its simulation task-dependent data are at least partially identical to the simulation task-dependent data of simulation task 22 assigned directly before it.

In the present example, simulation agent 18 A3 also finishes its assigned simulation 16 TC2_S1 as the second, so that another simulation task 22 is assigned to it afterwards. Since the next simulation task 22 of the second test scenario 14 in the simulation task processing list 20 is simulation 16 TC2_S5, and simulation agent 18 A3 has previously also completed simulation 16 of the second test scenario 14, simulation agent 18 A3 is assigned simulation 16 TC2_S5. Only after all simulation tasks 22 of the second test scenario 14 TC2_S(x) have been completed are the simulations 12 of the first test scenario 10 TC1_S(x) assigned to simulation agent 18 A3.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for assigning a plurality of simulation tasks to a plurality of simulation agents, the method comprising:
receiving a simulation task processing list comprising several simulation tasks to be completed;
assigning the simulation tasks to be completed to the simulation agents such that not all simulation tasks present in the simulation task processing list are assigned to the simulation agents;
checking, for the unassigned simulation tasks, whether simulation task-dependent data of the simulation task are at least partially identical to the simulation task-dependent data of the assigned simulation tasks; and
assigning at least one unassigned simulation task to a simulation agent, taking into account the check performed, such that, after the previously assigned simulation task has been completed, the simulation agent is assigned another simulation task, the simulation task-dependent data of which are at least partially identical to the simulation task-dependent data of the simulation task assigned immediately before it.

2. The method according to claim 1, wherein the step of assigning the simulation tasks to be completed to the simulation agents such that not all simulation tasks present in the simulation task processing list are assigned to the simulation agents, comprises an assignment of the simulation tasks to be completed to the simulation agents such that no more than one simulation task is assigned to each simulation agent.

3. The method according to claim 1, wherein the simulation agent is instructed not to remove the simulation task-dependent data after the simulation task has been completed.

4. The method according to claim 1, wherein the simulation agent is instructed to adopt the simulation task-dependent data of the previously completed simulation task, which are identified as identical, for the assigned simulation task before the start of the simulation task.

5. The method according to claim 1, wherein the simulation agent is instructed to remove the simulation task-dependent data of the previously completed simulation task, which are identified as non-identical, before the start of the simulation task.

6. The method according to claim 1, wherein the step of assigning the unassigned simulation tasks to the simulation agents is carried out taking into account the check such that a simulation task in the simulation task processing list is not assigned until a simulation agent has completed a previously assigned simulation task.

7. The method according to claim 1, wherein the step of receiving a simulation task processing list comprising several simulation tasks to be completed includes receiving an updated simulation task processing list.

8. The method according to claim 1, wherein the step of assigning the unassigned simulation tasks to the simulation agents is carried out taking into account the check such that a simulation agent is not assigned an unassigned simulation task with non-identical simulation task-dependent data until there are no more simulation tasks in the simulation task processing list, the simulation task-dependent data of which are completely identical to the simulation task-dependent data of the simulation tasks previously assigned to that simulation agent.

9. The method according to claim 1, wherein the assignment of the unassigned simulation tasks to the simulation agents is carried out taking into account the check such that a period of time for how long an unassigned simulation task is in the simulation task processing list is also taken into account.

10. The method according to claim 1, wherein the step of checking for the unassigned simulation tasks to see whether simulation task-dependent data of the simulation task are at least partially identical to the simulation task-dependent data of the assigned simulation tasks includes checking whether the unassigned simulation task is attributable to the same client as the assigned simulation task.

11. The method according to claim 1, wherein the step of checking for the unassigned simulation tasks to see whether simulation task-dependent data of the simulation task are at least partially identical to the simulation task-dependent data of the assigned simulation tasks involves checking whether the simulation task-dependent data are cross-client data or client-specific data.

12. The method according to claim 1, wherein the simulation task-dependent data comprise parameter sets for traffic scenarios and/or test cases of a simulation specified by the simulation task, software to be tested and/or a simulation environment of the simulation specified by the simulation task.

13. A computational environment for data processing comprising a computer for executing the method of claim 1.

14. A computer program product, comprising commands which, when executed by a computer, cause the computer to execute the method according to claim 1.

15. A computer-readable data carrier on which the computer program product according to claim 14 is stored.
